(19) United States
(12) Patent Application Publication
(10) Pub. No.: US 2005/0250020 A1
(43) Pub. Date: Nov. 10, 2005

(54) Mask, layout thereon and method therefor

(75) Inventors: Hsing-Tsun Liu, Hsinchu (TW); Jang-Tarng Lin, Hsinchu (TW); Ko-Wei Peng, Hsinchu (TW)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Mosel Vitelic, Inc., Science-Based Park Industrial Park (TW)

(21) Appl. No.: 10/943,078

(22) Filed: Sep. 15, 2004

(30) Foreign Application Priority Data
May 7, 2004 (TW) 093112975

(51) Int. Cl. G03C 5/00; G03F 9/00; G06F 17/50

(52) U.S. Cl. 430/5; 430/322; 716/19; 716/21

(57) ABSTRACT

A mask, the layout thereon and the method therefore are provided. In one embodiment, a mask layout structure comprises a plurality of unit patterns, wherein each unit pattern comprises a plurality of angle portions, and each angle portion has an extending portion extended outwardly therefrom. The mask can be used for defining the pattern of the photoresist layer before the ion implantation process. The use of the make layout structure not only avoids the lifting of the photoresist layer in the ion implantation process, but also produces outstanding features in the field of power devices. The mask can be used in the fabrication of power devices, especially in the fabrication of sources of trench power devices.

### CROSS-REFERENCES TO RELATED APPLICATIONS

This application claims priority from R.O.C. Patent Application No. 093112975, filed May 7, 2004, the entire disclosure of which is incorporated herein by reference.

### BACKGROUND OF THE INVENTION

The present invention relates to a mask, a layout structure thereon and a method therefor, which can be applied to the fabrication process of integrated circuits, and more particularly in the fabrication process of power devices.

In the fabrication process of integrated circuits, lithography is used for forming a layout structure or a layout pattern on a wafer. A mask with a layout structure is used in lithography for defining the layout structure on the photoresist layer, and then the development process is performed to form the photoresist layer with a desired layout structure.

Due to the optical effect, the shape of the layout structure developed on the photoresist layer is determined by the layout structure of the mask. In order to overcome the above optical effect, the layout structure of the mask shall be designed specifically so that a desired layout structure can be formed on the photoresist layer.

For implanting ions into part of the wafer area, before the ion implantation process, a development process shall be performed to form a photoresist layer with a layout structure for covering the specific areas against the ion implantation. When an improper layout structure is formed on the photoresist layer, a lifting phenomenon of the photoresist layer will be caused by the impact of ion implantation, as shown in FIGS. 1(a) and 1(b). FIG. 1(a) shows the scanning electron microscope (SEM) photograph of the photoresist arrangement before an ion implantation process, whereas FIG. 1(b) shows the scanning electron microscope (SEM) photograph of the photoresist arrangement after an ion implantation process.

The possible reasons for the lifting of the photoresist layer include the quality of the photoresist layer and the improper implantation energy. However, the improper layout structure on the photoresist layer is another possible reason for the lifting of the photoresist layer. FIG. 2 shows a schematic diagram of the corner roundings of the layout structure on the photoresist layer. The layout structure of the mask (not shown) includes a plurality of identical unit patterns 21. As shown in FIG. 2, each identical unit pattern 21 will cause the corner roundings of the corresponding photoresist pattern 16. Because the contact area between the photoresist layer and the wafer (not shown) will be reduced due to the corner roundings, the relevant adhesion between the photoresist layer and the wafer is decreased accordingly. Since the wafer surface is impacted with ions in the ion implantation process, there will be a strong impact force thereon. As the impact force will cause part of the photoresist layer to be lifted, the effect of the ion implantation process will be manifested.

From the above description, how to develop a new mask, a layout thereon and the method therefor so as to reduce the lifting of the photoresist layer caused by the ion implantation process has become a major problem that needs to be solved. In order to overcome the drawbacks in the prior art, a new mask, the layout thereon and the method therefor are provided. The particular design in the present invention not only solves the problems described above, but also is easy to be implemented. Thus, the invention has the utility for the industry.

### BRIEF SUMMARY OF THE INVENTION

Embodiments of the present invention provide a mask, the layout thereon and the method therefor, which are used for defining the pattern of the photoresist layer before the ion implantation process. The present invention not only avoids the lifting of the photoresist layer in the ion implantation process, but also produces outstanding features in the field of power devices. The present invention can be used in the fabrication of power devices, especially in the fabrication of sources of trench power devices.

In accordance with an aspect of the present invention, a mask layout structure comprises a plurality of unit patterns, wherein each unit pattern comprises a plurality of angle portions, and each angle portion has an extending portion extended outwardly therefrom.

In some embodiments, the mask layout structure is used for defining a pattern of a photoresist layer before an ion implantation process for an integrated circuit. The integrated circuit is a power device. The power device is a trench power device. The ion implantation process is used to form a source of the power device. The extending portion comprises at least one sub-extending portion, and an area of the sub-extending portion is less than an area of the extending portion. The extending portion and the sub-extending portion are L-shaped. The unit patterns are identical.

In accordance with another aspect of the invention, a mask comprises a layout structure having a plurality of unit patterns, wherein each unit pattern comprises a plurality of angle portions, and each angle portion has an extending portion extended outwardly therefrom.

In accordance with another aspect of the invention, a method for forming a first layout structure comprises (a) providing a second layout structure having a plurality of unit patterns, wherein each unit pattern comprises a plurality of angle portions, and each angle portion comprises two edges; (b) searching at least one of the angle portions; (c) selecting one of the angle portions, wherein an included angle formed by the edges of the selected angle portion is an angle of about 90 degrees; and (d) forming an extending portion by extending the unit pattern from the selected angle portion outwardly to form the first layout structure.

In specific embodiments, the first layout structure is used for defining a pattern of a photoresist layer before an ion implantation process for an integrated circuit for defining a pattern of a photoresist layer. The extending portion comprises at least one sub-extending portion. The method further comprises (e) selecting the at least one sub-extending portion; and (f) forming a sub-sub-extending portion extended from the selected sub-extending portion. The sub-sub-extending portion has an area less than an area of the sub-extending portion. The sub-extending portion and the sub-sub-extending portion are L-shaped.

### BRIEF DESCRIPTION OF THE DRAWINGS

FIG. 1(a) shows the scanning electron microscope (SEM) photograph of the photoresist arrangement before an ion implantation process;

FIG. 1(b) shows the scanning electron microscope (SEM) photograph of the photoresist arrangement after an ion implantation process;

FIG. 2 is a schematic diagram showing the corner roundings of the layout structure on the photoresist layer in the prior art;

FIG. 3 is a schematic diagram showing the source ion implantation process for a power device in the prior art;

FIG. 4 is a top view of the layout structure on the photoresist layer;

FIG. 5(a) is a schematic diagram showing a layout structure according to one embodiment of the present invention; and

FIG. 5(b) is a schematic diagram showing a layout structure according to another embodiment of the present invention.

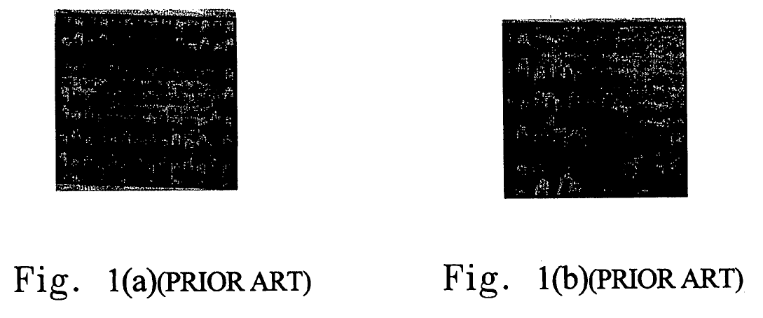

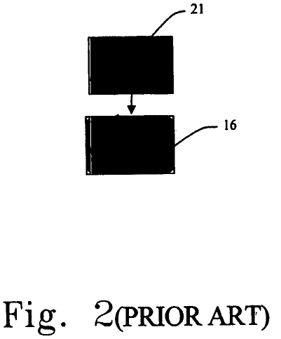

### DETAILED DESCRIPTION OF THE INVENTION

The present invention will now be described more specifically with reference to the following embodiments. It is to be noted that the following descriptions of preferred embodiments of this invention are presented herein for purpose of illustration and description only; it is not intended to be exhaustive or to be limited to the precise form disclosed.

In order to overcome the problem of the lifting of the photoresist layer after performing the ion implantation process, the present invention proposes a novel layout structure to solve the drawbacks described above.

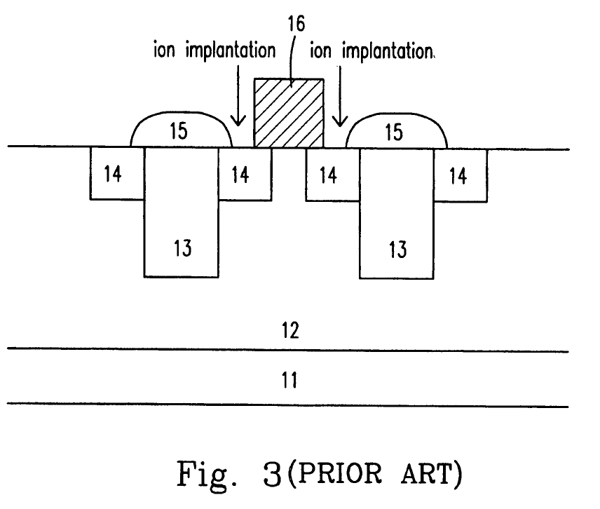

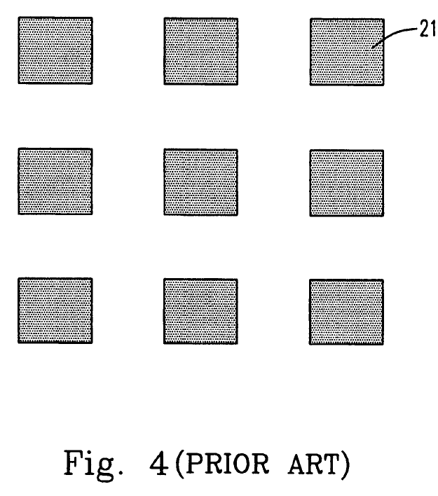

FIG. 3 shows a schematic diagram of the source ion implantation process for a power device in the prior art. Preferably, the power device is a trench power device, which includes a drain 11, a substrate 12, a gate 13, a source 14 and an insulating layer 15. Before performing the source ion implantation process for the power device, a lithography process is performed to define photoresist patterns 16 for covering the specific areas on the wafer (not shown) against the ion implantation, in which the layout structure of the mask for defining photoresist patterns in the lithography is shown in FIG. 4. As seen in FIG. 4, the layout structure of the mask includes a plurality of identical unit patterns 21.

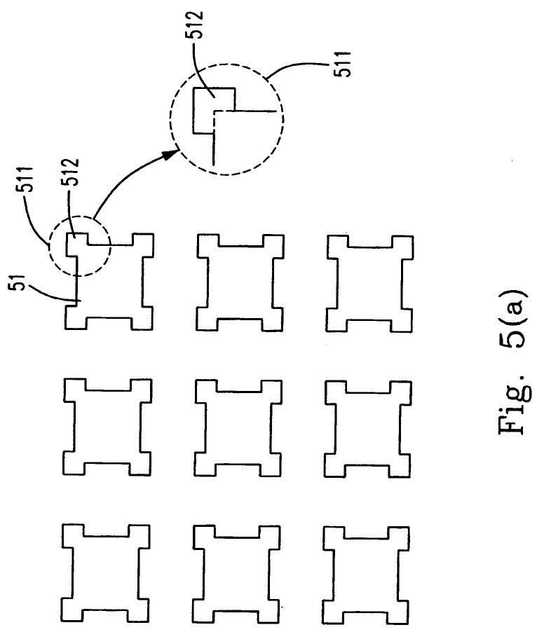

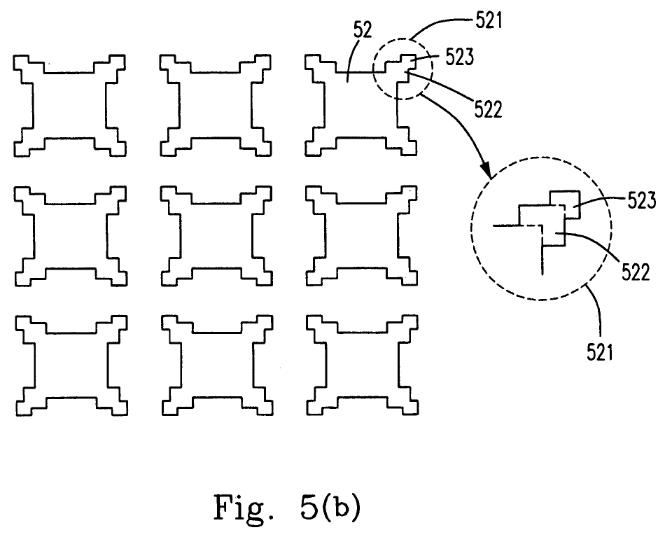

FIG. 5(a) shows a schematic diagram of a layout structure (or a mask layout structure) according to one embodiment of the present invention. The layout structure includes a plurality of identical unit patterns 51, wherein each identical unit pattern 51 includes four angle portions 511, and each angle portion 511 has an extending portion 512 extended outwardly therefrom. Preferably, the extending portion 512 is L-shaped.

As shown in FIG. 5(a), the extending portion 512 is formed on each angle portion 511 of each unit pattern 51 so as to increase the area of each angle portion 511.

Therefore, the corner roundings will not occur if the layout structure of FIG. 5(a) is implemented to define the photoresist pattern for covering the specific areas on the wafer against the ion implantation. In addition, the contact area between the photoresist layer and the wafer will become larger so that the adhesion therebetween will be enhanced as well. This prevents part of the photoresist layer from being lifted by the strong impact force after performing the source ion implantation process.

FIG. 5(b) shows a schematic diagram of a layout structure according to another embodiment of the present invention. The layout structure includes a plurality of identical unit patterns 52, wherein each identical unit pattern 52 includes four angle portions 521, and each angle portion 521 has a sub-extending portion 522 and a sub-sub-extending portion 523. In which, the sub-sub-extending portion 523 is formed by extending the sub-extending portion 522 outwardly and has an area smaller than the sub-extending portion 522. Preferably, the sub-extending portion 522 and the sub-sub-extending portion 523 are L-shaped.

The area of the extending portion is increased in the embodiment shown in FIG. 5(b) so that the area of each angle portion 521 is increased accordingly. Thus, through employing the layout structure shown in FIG. 5(b) to define the photoresist patterns for covering the specific areas on the wafer against the ion implantation, a preferred photoresist pattern can be defined so that the occurrence of corner roundings could be avoided accordingly. As a result, the contact areas between the photoresist layer and the wafer will be increased so that the adhesion therebetween will be enhanced as well. This prevents part of the photoresist layer from being lifted by the strong impact force resulted from the source ion implantation process.

The present invention has the advantage of avoiding the lifting of the photoresist layer in the ion implantation process. The present invention is applicable not only in the source ion implantation process, but also in ion implantations used for adjusting device voltages, impedance values or any other purposes. Moreover, the present invention can also be applied in the etching process where the photoresist layer is used as a barrier layer. Further, the present invention possesses outstanding features in the field of power devices.

In addition, a mask with the above layout structure is also provided. In other words, the scope of the present invention covers the mask and the layout structure.

The layout structure of the embodiments of the present invention may be fabricated by the optical proximity correction (OPC) technology. The fabrication steps of the layout structure are described as follows.

(a) A desired layout structure for the photoresist layer, i.e., the pattern shown in FIG. 4, is provided. The desired layout structure includes a plurality of identical unit patterns, i.e., rectangular patterns or other desired patterns. In the layout structure, each identical unit pattern includes four angle portions, and each angle portion includes two edges.

(b) At least one of the angle portions is searched.

(c) One of the angle portions is selected, wherein the included angle formed by the edges of the selected angle portion is at about 90 degrees (slight errors are acceptable).

(d) An extending portion is formed by extending the selected angle portion outwardly, such as the extending portion 512 shown in FIG. 5(a).

After the above steps, the layout structure shown in FIG. 5(a) can be fabricated. However, for fabricating the layout structure shown in FIG. 5(b), additional steps shall be performed since the extending portion therein includes at least one sub-extending portion.

(e) At least one sub-extending portion is selected, such as the sub-extending portion 522 shown in FIG. 5(b).

(f) A sub-sub-extending portion (such as the sub-sub-extending portion 523 shown in FIG. 5(b)) extended from the selected sub-extending portion (such as the sub-extending portion 522 shown in FIG. 5(b)) is formed.

The method for forming the layout structures according to the embodiments of the present invention can be achieved with a general OPC software. Therefore, part of the terms described above, such as “provided” and “searched” and “selected” and so on, shall correspond to the relevant terms of the software technology based on the purposes of the present invention. For instance, “loaded” may stand for “provided”.

In view of the aforesaid description, the problem associated with corner roundings of the photoresist layer can be overcome by utilizing the mask and layout structure thereon provided by the embodiments of the present invention. Hence, the contact areas between the photoresist layer and the wafer will be increased so that the adhesion therebetween will be enhanced as well. This prevents part of the photoresist layer from being lifted by the strong impact force resulted from the source ion implantation process. Accordingly, the present invention can effectively overcome the problems and drawbacks in the prior arts, and thus meets the demands of the industry and is industrially valuable.

While the invention has been described in terms of what is presently considered to be the most practical and preferred embodiments, it is to be understood that the invention needs not be limited to the disclosed embodiment. On the contrary, it is intended to cover various modifications and similar arrangements include within the spirit and scope of the appended claims which are to accord with the broadest interpretation so as to encompass all such modification and similar structures.

1. A mask layout structure, comprising:
a plurality of unit patterns, wherein each said unit pattern comprises a plurality of angle portions, and each said angle portion has an extending portion extended outwardly therefrom.

2. The mask layout structure as claimed in claim 1, wherein said mask layout structure is used for defining a pattern of a photoresist layer before an ion implantation process for an integrated circuit.

3. The mask layout structure as claimed in claim 2, wherein said integrated circuit is a power device.

4. The mask layout structure as claimed in claim 3, wherein said power device is a trench power device.

5. The mask layout structure as claimed in claim 3, wherein said ion implantation process is used to form a source of said power device.

6. The mask layout structure as claimed in claim 1, wherein said extending portion comprises at least one sub-extending portion, and an area of said sub-extending portion is less than an area of said extending portion.

7. The mask layout structure as claimed in claim 6, wherein said extending portion and said sub-extending portion are L-shaped.

8. The mask layout structure as claimed in claim 6, wherein said unit patterns are identical.

9. A mask, comprising:
a layout structure having a plurality of unit patterns, wherein each said unit pattern comprises a plurality of angle portions, and each said angle portion has an extending portion extended outwardly therefrom.

10. The mask as claimed in claim 9, wherein said layout structure is used for defining a pattern of a photoresist layer before an ion implantation process for an integrated circuit.

11. The mask as claimed in claim 10, wherein said integrated circuit is a power device.

12. The mask as claimed in claim 11, wherein said power device is a trench power device.

13. The mask as claimed in claim 11, wherein said ion implantation process is used to form a source of said power device.

14. The mask as claimed in claim 9, wherein said extending portion comprises at least one sub-extending portion, and an area of said sub-extending portion is less than an area of said extending portion.

15. The mask as claimed in claim 14, wherein said extending portion and said sub-extending portion are L-shaped.

16. The mask as claimed in claim 9, wherein said unit patterns are identical.

17. A method for forming a first layout structure, comprising:
(a) providing a second layout structure having a plurality of unit patterns, wherein each said unit pattern comprises a plurality of angle portions, and each said angle portion comprises two edges;
(b) searching at least one of said angle portions;
(c) selecting one of said angle portions, wherein an included angle formed by said edges of said selected angle portion is an angle of about 90 degrees; and
(d) forming an extending portion by extending the unit pattern from said selected angle portion outwardly to form said first layout structure.

18. The method as claimed in claim 17, wherein said first layout structure is used for defining a pattern of a photoresist layer before an ion implantation process for an integrated circuit for defining a pattern of a photoresist layer.

19. The method as claimed in claim 18, wherein said integrated circuit is a power device.

20. The method as claimed in claim 19, wherein said power device is a trench power device.

21. The method as claimed in claim 19, wherein said ion implantation process is used to form a source of said power device.

22. The method as claimed in claim 17, wherein said extending portion comprises at least one sub-extending portion.

23. The method as claimed in claim 22, further comprising:
(e) selecting said at least one sub-extending portion; and
(f) forming a sub-sub-extending portion extended from said selected sub-extending portion.

24. The method as claimed in claim 23, wherein said sub-sub-extending portion has an area less than an area of said sub-extending portion.

25. The method as claimed in claim 24, wherein said sub-extending portion and said sub-sub-extending portion are L-shaped.
